(19) United States
(12) Patent Application Publication
(10) Pub. No.: US 2007/0037074 A1
(43) Pub. Date: Feb. 15, 2007

(54) Use of alternative polymer materials for "soft" polymer pellicles

(76) Inventors: Alexander Tregub, Oak Park, CA (US); Florence Eschbach, Portola Valley, CA (US); Fu-Chang Lo, Palo Alto, CA (US)

Correspondence Address: FISH & RICHARDSON, PC, P.O. BOX 1022, MINNEAPOLIS, MN, 55440-1022, US

(21) Appl. No.: 11/585,737

(22) Filed: Oct. 23, 2006

Related U.S. Application Data
(63) Continuation of application No. 10/799,928, filed on Mar. 12, 2004.

(51) Int. Cl. A47G 1/12; C08L 27/12; G03F 1/14; G03F 1/00; C08F 214/26

(52) U.S. Cl. 430/5; 525/199; 525/200; 428/14

(57) ABSTRACT

Disclosed are pellicle compositions and methods of making such pellicle compositions. The pellicle compositions provided include highly fluorinated polymers as well as fluorinated polymer/PVDF co-polymers.

### CROSS-REFERENCE TO RELATED APPLICATIONS

This application is a divisional application of and claims priority to U.S. patent application Ser. No. 10/799,928, filed Mar. 12, 2004.

### TECHNICAL FIELD

The disclosure relates to polymers, and more particularly to polymers useful as pellicles in photolithography.

### BACKGROUND

Pellicles are membranes used during lithography. A pellicle is placed a desired distance from either the front side or the backside of a mask. Pellicles may be used to block particles that are in the focal plane from reaching the mask or reticle surface. Any particles on the pellicle surface are out of the focal plane and hence should not form an image on the wafer being exposed. A pellicle is a thin transparent layer stretched over a frame above the surface of a mask or reticle. Typically the pellicle is transparent to laser light. Applied laser energy will depend on pellicle and resist transmission. For example, critical dimensions of the printed resist features are very sensitive to the variation dose of laser energy. A 2% difference in dose can result in 10% variation in critical dimensions.

### DESCRIPTION OF DRAWINGS

FIG. 1 is a plot showing the effect of exposure dose on transmission for CYTOP pellicles exposed to 157 nm irradiation.

FIG. 2 is a plot showing the effect of exposure dose on transmission for Teflon AF (TAF) pellicle exposed to 157 nm irradiation.

FIG. 3 is a plot showing a comparison of transmission between fluorinated polyvinylidiene fluoride (PVDF; 1,1-di-fluoro-ethylene) and PVDF exposed to 157 nm irradiation.

FIG. 4 shows experimental and calculated values of transmission of PVDF film at 193 nm.

FIG. 5 shows the optical testing of PVDF KYNAR at 1 ppm oxygen.

FIG. 6 is a plot showing the transmission at different wavelengths of fluorinated and non-fluorinated high molecular weight polymers.

FIG. 7 is a plot showing the transmission at 157 nm for a fluorinated copolymer that comprises oxygen and fluorine atoms compared to a non-fluorinated copolymer.

FIG. 8 shows a comparison of the FTIR spectra for fluorinated and non-fluorinated polymers that comprise oxygen and fluorine atoms.

FIG. 9 is a plot showing the dependence of transmission on irradiation dose for 157 nm exposure. A pellicle made using co-polymer A (a cyclic fluorocarbon oxygen-containing polymer) and PVDF shows higher transmission and durability than the pellicle made using polymer A alone.

### DETAILED DESCRIPTION

The disclosure provides pellicle materials that have comparable durability and transmissibility as that of an amorphous, soluble perfluoropolymer CYTOP and are readily available. PVDF can serve as a CYTOP replacement for 193 nm lithography. The optical transmission of PVDF at 193 nm, measured for 1 μm thick film, is equal to 95.5% of CYTOP. PVDF is also soluble in organic solvents and can be used for spin on technology for the generation of pellicles. PVDF's durability at 157 nm is comparable with that of CYTOP and can be further improved by fluorination, purification, and internal stress relief. Accordingly, a pellicle system comprising a PVDF pellicle composite/copolymer material is described. Furthermore, the use of 157 nm wavelength irradiation has proven important in some photolithography techniques. CYTOP shows poor transmissibility and durability when used at shorter wavelengths (e.g., 157 nm). This disclosure further provides pellicle materials having improved durability and transmissibility at 157 nm wavelength irradiation.

Pellicles are used as a photomask protective cover in the projection printer or wafer/mask stepper process to increase the yield of the process. The pellicle is a thin transparent membrane adhered to a frame, which guards a photomask or reticle from harmful particle contamination.

In the lithographic industry, ultraviolet rays of wavelengths: 248 nm and 193 nm are used as exposure light, and with fining of patterns. Far-ultraviolet rays, vacuum ultraviolet rays, electron beam (EB), X-rays, and the like, which have shorter wavelengths, have been used as exposure lights. KrF excimer laser beams having wavelengths of 248 nm, ArF excimer laser beams having wavelengths of 193 nm, and F2 laser beams having wavelengths of 157 nm are being used and are expected to be useful for the formation of fine patterns.

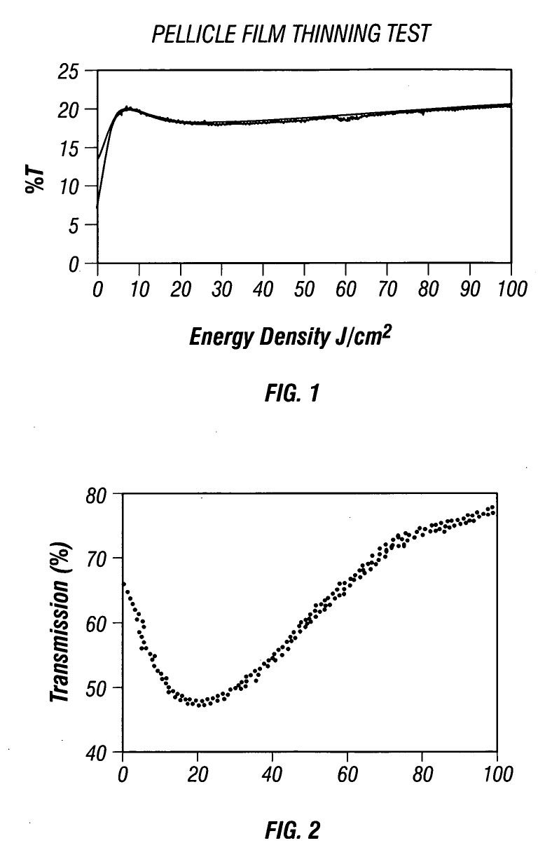

Most pellicle polymers are useful at wavelengths of 193 nm but degrade rapidly at shorter wavelengths (e.g., at 157 nm). Irradiation of polymer pellicles causes pellicle structural degradation that depends on the irradiation dose and wavelength (or energy) of irradiation. For example, irradiation of pellicles made from CYTOP (an amorphous, soluble perfluoropolymer) or Teflon AF polymer (polytetrafluoroethylene amorphous fluoropolymer) with 157 nm in the range from 1 to 100 J/cm² causes a drop of transmission by as much as 100%. In addition, relying on the transmission properties of CYTOP or TAF at a particular irradiation dose is not practical. FIG. 1 shows the dependence of transmission on irradiation dose for CYTOP exposed to 157 nm irradiation. CYTOP shows a low transmission rate (˜20%) and further shows that fluorination has little to no effect on transmission or durability of CYTOP. FIG. 2 shows the effect of exposure dose on transmission for TAF pellicle exposed to 157 nm. TAF shows a large transmission variation that is unacceptable for lithography processes. Low transmission and high variations in transmission, observed for CYTOP and TAF (FIGS. 1 and 2), respectively, are unacceptable for lithograph processes. A pellicle material that has sufficient durability or transmits a light in the ultraviolet region of shorter wavelength, particularly the vacuum ultraviolet (VUV) region such as a region of F2 laser beam of 157 nm is desirable.

Furthermore, the dose should be uniform over the surface of a pellicle and wafer and should not change during the life of the pellicle. Deviations in transmission by less than 1% can typically be adjusted by an appropriate increase in exposure time (typically through automated adjustments) to take into account loss of transmission. For deviations above 1%, a process lithography engineer needs to make time consuming calculations. If the change in the pellicle transmission is not adequately corrected a change of critical dimensions (CD) on the exposed wafer will occur. This change depends, in part, on the resist thickness, absorption, type, and the like.

Disclosed are co-polymer composition comprising PVDF and an amorphous fluoropolymer. Amorphous fluoropolymers are known in the art and include, but are not limited to, materials comprising a cyclic fluorocarbon oxygen-containing polymer, a polyimide linear fluoropolymer, perfluorinated polyethers, and combinations thereof. PVDF, fluorinated PVDF, and non-fluorinated PVDF can be used in the co-polymer composition. As described herein pellicles comprising such PVDF-amorphous fluoropolymer are provided by the disclosure.

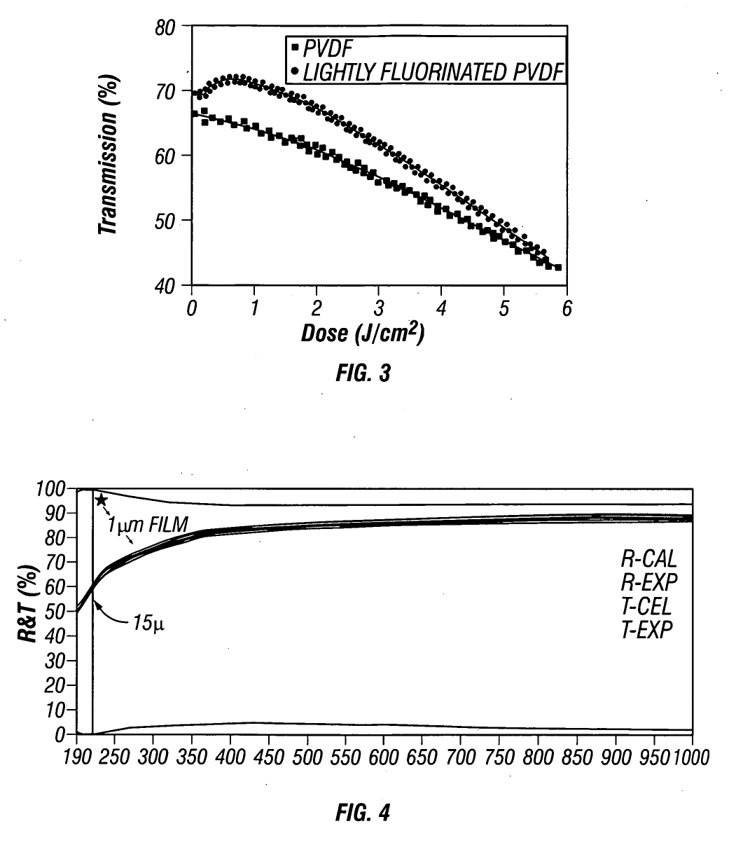

PVDF comprises two hydrogen and two fluorine atoms in its structure (see scheme 1). Further fluorination can improve both transmission and durability of the fluorinated PVDF (see, FIG. 3). In addition, PVDF shows high transmission at 193 nm as discussed herein. 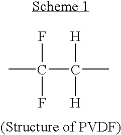
Scheme 1 shows the structure of PVDF. FIG. 4 shows experimental and calculated values of transmission of PVDF film at 193 nm. Dependence of transmission on the wavelength from 190 nm to about 1000 nm for 15 μm thick PVDF film was determined experimentally using n and k tool 151 2RT (see, e.g., FIG. 4). Transmission for 1 μm thick film was calculated using log (1/T)=tA, where T is transmission, t is film thickness, and A is absorption, the data is presented in FIG. 4 (star).

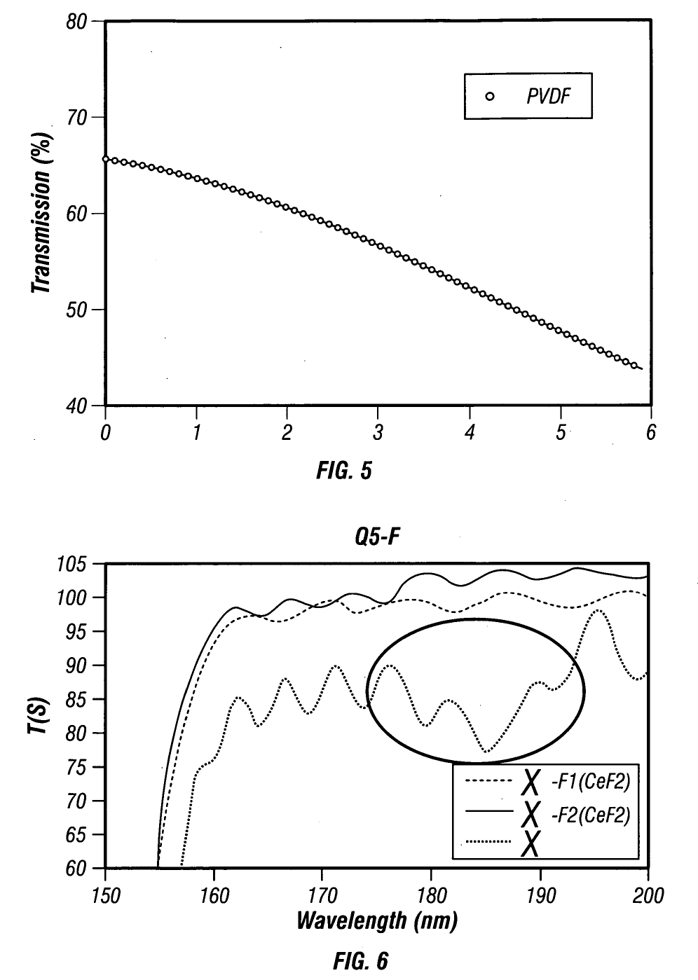

Optical tests performed using PVDF KYNAR polymer film are shown in FIG. 5. FIG. 5 demonstrates that the percent transmission at 157 nm degrades for commercially available PVDF, however, the loss of transmission is comparable with those measured for CYTOP and is significantly better that the loss of transmission measured for TAF (see, also Table 1).

TABLE 1

| | | | Platform | Teflon AF | |
|---|---|---|---|---|---|
| Polymer | PVDF | Platform A | B | (TAF) | CYTOP |
| Loss of | 30 | 20 | 25 | ˜80 | NA: |
| transmission | | | | | membrane |
| (%) | | | | | thinning |
| Transmission | 65 | 87 | 95 | 90 | 10-20 |
| of non- | | | | | |
| exposed | | | | | |
| polymer | | | | | |
| Tested | 1 | 1 | 1 | 1 | 1 |
| oxygen | | | | | |
| content | | | | | |
| (ppm) | | | | | |
| Dose, at | 6 | 6 | 6 | 6 | 6 |
| which | | | | | |
| comparison | | | | | |
| is | | | | | |
| conducted, | | | | | |
| J/cm² | | | | | |

In addition to PVDF being useful as a pellicle material at a wavelength of 193 nm, fluorinated PVDF having improved pellicle characteristics is provided. The disclosure provides fluorinated PVDF having improved optical transmission and durability compared to a PVDF having a monomeric structure as set forth in Scheme 1, particularly at wavelengths shorter than 193 nm (e.g., 157 nm). Accordingly, PVDF that has been subject to further fluorination may also serve as a polymer pellicle at shorter wavelenghths either alone or as a copolymer material.

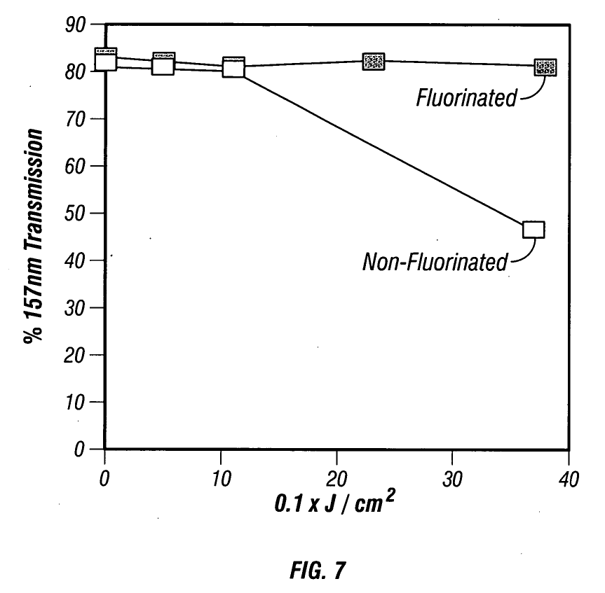

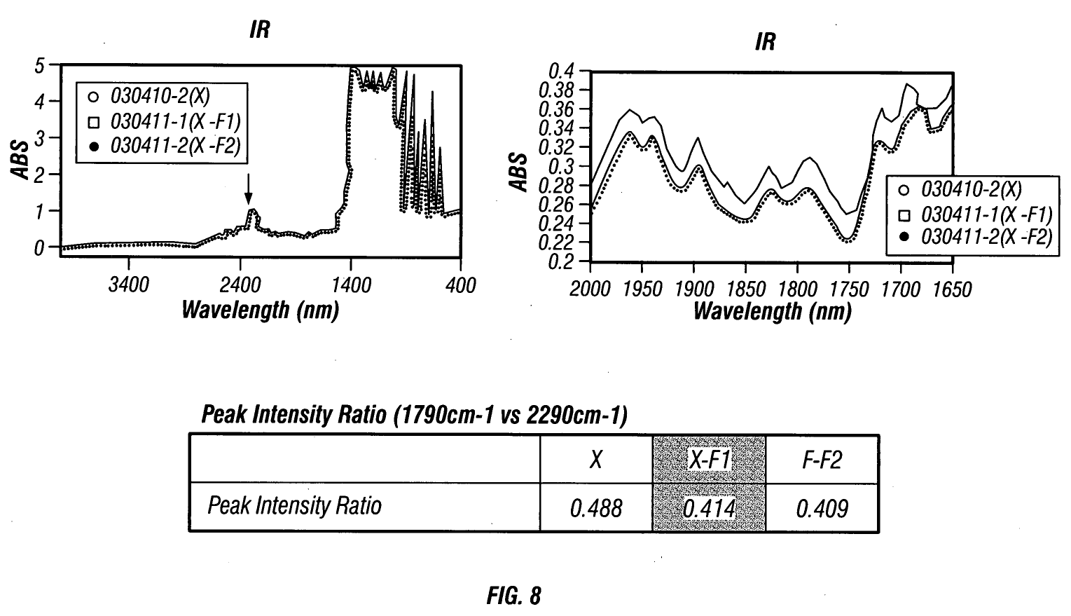

Fluorination of PVDF improved optical properties, such as durability and transmission as shown in FIG. 6. FIG. 6 shows transmission data at different wavelengths for a fluorinated and non-fluorinated high molecular weight polymer comprising oxygen and fluorine. Transmission increased when contacted with a wavelength range from about 157 nm to 200 nm after fluorination as shown in FIG. 6. FIG. 7 further shows the improvement in transmission and durability. As shown in FIG. 7 the fluorinated copolymer (top line) did not degrade up to 40 J/cm² compared to the non-fluorinated copolymer. Such fluorination changes the molecular structure of the polymers, as shown using FTIR and molecular weight tests in FIG. 8 and Table 1. FIG. 8 shows a comparison of the FTIR spectra for fluorinated and non-fluorinated polymers that comprise oxygen and fluorine atoms. Peaks at 2290 cm⁻¹ are assigned to hydrogen atoms, while peaks at 1790 cm⁻¹ are assigned to CF bonds. F1 and F2 designate lower and higher fluorination levels, respectively. As fluorination levels increase, peak intensity ratios decrease, which indicates an increase in fluorine content in the polymers. Increases in transmission are a result of replacement of non-reacted residual hydrogen atoms with fluorine atoms on both end groups and the main chain. Table 2 shows that as fluorination increases, intrinsic viscosity also increases.

TABLE 2

| Polymer | Intrinsic Viscosity |
|---|---|
| Non-fluorinated | 1.454 |
| polymer | |
| Fluorinated F1 | 1.681 |
| Fluorinated F2 | 1.691 |
| Fluorinated F3 | 1.679 |

Of particular interest are pellicles comprising PVDF copolymers comprising PVDF (fully-, partially, and non-fluorinated) and (i) a cyclic fluorocarbon oxygen-containing polymer, (ii) a polyimide linear fluoropolymer, (iii) perfluorinated polyethers, or (iv) composites of any of (i)-(iii).

The use of PVDF copolymers in pellicle optimizes pellicle synthesis, improves pellicle plasticity and improves optical properties, to name a few advantages. PVDF has flexible macromolecular chains such that insertion the blocks of copolymer into a rigid polymer membrane makes the membranes less rigid and more “soft”. High rigidity of polymer films can cause film breakdown during pull-out of thin polymer membranes during spin coating. Inserting PVDF blocks (including PVDF blocks that have been further fluorinated) into the original polymer structure can improves optical properties of the pellicles as well as pellicle synthesis.

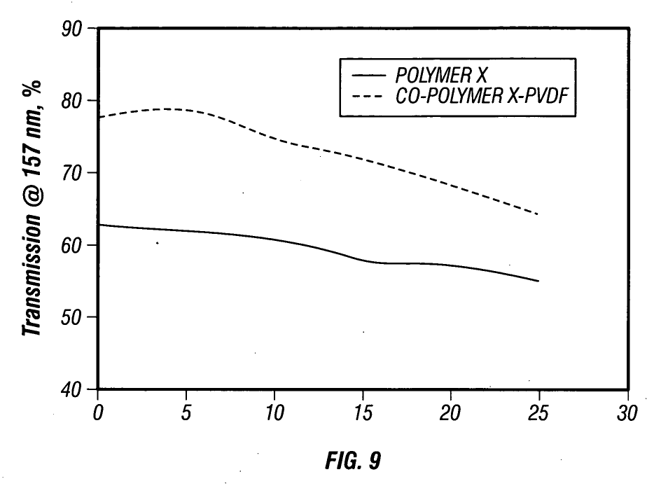

The PVDF polymers and copolymers are useful as pellicles for a number of reasons. For example, PVDF copolymers have (i) improved optical properties including high transmission percentages at 157 nm due to the presence of alternating CF₂-CH₂ segments breaking sigma sigma conjugation of C-C bonds, and (ii) better durability than homopolymers due to the introduction of a linear portion in the polymer backbone. The linear component allows for free radical propagation along the main chain delaying polymer backbone or main chain breakdown. FIG. 9 shows the dependence of transmission on irradiation dose for 157 nm exposure of a pellicle made using co-polymer A (a cyclic fluorocarbon oxygen-containing polymer) and a pellicle made using PVDF. FIG. 6 shows a higher transmission (approximately 98%) and durability (˜40J/cm²) than a pellicle made using only polymer A (80% transmission, ˜20J/cm² durability). In addition, FIG. 9 shows that co-polymers of A and another polymer B (a fluorocarbon polymer with reduced oxygen content comprising a ring and a linear chain appropriate for pellicle manufacturing) does not show improvement in durability and transmission. PVDF's ability to improve pellicle properties when used as a co-polymer is unique.

A pellicle is typically produced by using a solution of the fluorine-containing polymer. Any solvent can be used so long as it dissolves the polymer. Common solvents include fluorine-containing solvents in which the polymer is highly soluble. For example, common solvents may include polyfluoroaromatic compounds such as perfluorobenzene, pentafluorobenzene and 1,3-bis(trifluormethyl) benzene. Polyfluorotrialkylamine compounds such as, for example, perfluorotribuylamine and perfluortripropylamine are also useful. In addition, polyfluorocycloalkane compounds such as perfluoroocyclohexane are useful as well as polyfluorocyclic ether compounds (e.g., perfluoro (2-butyltetrahydrofuran)).

A pellicle membrane is formed from a layer of polymer on a substrate by any number of methods such as, for example, roll coating, casting, dip coating, spin coating, water casting, or die coating. The thickness of the pellicle is usually selected to be in a range from about 0.01 to 50 μm. Typical substrates may include silicon wafer, quartz glass, or the like, having a smooth surface.

Pellicles are typically manufactured using spin-on technology. As such, pellicle polymers combine high optical clarity at certain wavelengths and solubility. CYTOP and Teflon AF (TAF) are commonly used pellicle materials that possess high optical clarity and good solubility as a consequence of their amorphous morphology attributed to their cyclic structure. Although fluoropolymers show high optical transparency, many fluoropolymers are not soluble in organic solutions. Thus, most fluoropolymers are not applicable to spin-on of the polymer solutions. As such, an appropriate alternative material for pellicle manufacturing should combine high optical clarity, durability and solubility in the organic solutions. Pellicles comprising PVDF satisfy this need. Certain solvents such as methyl ethyl ketone (MEK) are acceptable for spin coating of PVDF copolymers on most surfaces of relevance, for film thicknesses typical of present-day commercial applications.

Accordingly, a method comprising coating a fluorine-containing polymer and PVDF copolymer composition on a substrate is provided by the disclosure. The method comprises coating on a substrate a fluorine-containing polymer and PVDF copolymer composition dissolved in a solvent, and drying the solvent such that a thin film of the fluorine-containing polymer and PVDF copolymer is formed on the substrate. As described herein various amorphous fluorine containing polymer materials are known in the art. The coating of the copolymer material can be performed in any number of ways including roll coating, dip coating, spin coating, water casting, and die coating. Using the methods provided, a pellicle film can be easily generated and used for lithography purposes.

Fluorination of PVDF can be accomplished using a number of techniques. For example, post-formation fluorination of polymer materials useful as pellicles is provided by the disclosure. Physical and chemical modifications of PVDF and polymer materials contribute to the durability and optical properties of the materials and polymers, particularly at shorter wavelengths. The polymer surface characteristics (including end atoms) have a strong influence on the final product's physical and chemical properties.

An aspect describes improving PVDF pellicle and polymer characteristics such as durability and optical transmission by surface treatment techniques. Various surface modification techniques may include, for example, chemical treatment; flame treatment; coronas; low pressure plasmas; IR, UV, X-ray and gamma-ray irradiation; electron and ion beam bombardment; ozone exposure; plasma treatment; and others.

A number of embodiments have been described. Nevertheless, it will be understood that various modifications may be made without departing from the spirit and scope of the disclosure. Accordingly, other embodiments are within the scope of the following claims.

What is claimed is:

1. A lithography method comprising:
placing a pellicle comprising polyvinylidene fluoride (PVDF) on a side of a lithography mask; and
transmitting an electromagnetic radiation through the pellicle to form a lithographic image on a substrate.

2. The method of claim 1, wherein placing the pellicle on the side of the lithography mask comprises placing a pellicle comprising a copolymer of PVDF on the side of the lithography mask.

3. The method of claim 2, wherein placing the pellicle comprises placing a pellicle comprising a block copolymer of PVDF on the side of the lithography mask.

4. The method of claim 2, wherein placing the pellicle comprises placing a pellicle comprising a copolymer of PVDF and an amorphous fluoropolymer on the side of the lithography mask.

5. The method of claim 4, wherein placing the pellicle comprises placing a pellicle comprising a copolymer of PVDF and a cyclic fluorocarbon oxygen-containing polymer on the side of the lithography mask.

6. The method of claim 4, wherein placing the pellicle comprises placing a pellicle comprising a copolymer of PVDF and a polyimide linear fluoropolymer on the side of the lithography mask.

7. The method of claim 4, wherein placing the pellicle comprises placing a pellicle comprising a copolymer of PVDF and a perfluorinated polyether on the side of the lithography mask.

8. The method of claim 4, wherein placing the pellicle comprises placing a pellicle comprising a copolymer of PVDF and a combination of two or more of a cyclic fluorocarbon oxygen-containing polymer, a polyimide linear fluoropolymer, and a polyimide linear fluoropolymer on the side of the lithography mask.

9. The method of claim 1, wherein placing the pellicle on the side of the lithography mask comprises placing a fluorinated pellicle on the side of the lithography mask.

10. The method of claim 1, wherein placing the pellicle on the side of the lithography mask comprises placing a surface-modified pellicle on the side of the lithography mask.

11. The method of claim 1, wherein placing the pellicle on the side of the lithography mask comprises stretching the pellicle over a frame above a surface of the mask.

12. The method of claim 1, wherein transmitting the electromagnetic radiation comprises transmitting one or more of ultraviolet and far ultraviolet through the pellicle.

13. The method of claim 1, further comprising spinning a solution that includes PVDF on a substrate.

14. The method of claim 1, further comprising correcting for a change in transmissivity of the pellicle to the electromagnetic radiation.

15. The method of claim 14, wherein correcting for the change in transmissivity of the pellicle comprises correcting for the change in transmissivity only after the pellicle has been exposed to more that about 12 J/cm² of 157 nm wavelength radiation.

16. The method of claim 14, wherein correcting for the change in transmissivity of the pellicle comprises correcting for the change in transmissivity only after the pellicle has been exposed to more that about 40 J/cm² of 157 nm wavelength radiation.

17. The method of claim 1, further comprising:
stepping to a second position relative to the substrate; and
transmitting the electromagnetic radiation through the pellicle to form a second copy of the lithographic image on the substrate.
